(19) United States
(12) Patent Application Publication
(10) Pub. No.: US 2006/0125059 A1
(43) Pub. Date: Jun. 15, 2006

(54) Semiconductor wafer with protection structure against damage during a die separation process

(75) Inventors: Hsien-Wei Chen, Sinying City (TW); Hao-Yi Tsai, Hsinchu City (TW); Shih-Hsun Hsu, Keelung City (TW); Bai-Yao Lou, Hsinchu City (TW)

Correspondence Address: DUANE MORRIS, LLP;IP DEPARTMENT, 30 SOUTH 17TH STREET, PHILADELPHIA, PA, 19103-4196, US

(73) Assignee: Taiwan Semiconductor Manufacturing Co., Ltd.

(21) Appl. No.: 11/012,760

(22) Filed: Dec. 15, 2004

(51) Int. Cl. H01L 23/544

(52) U.S. Cl. 257/620

(57) ABSTRACT

A semiconductor wafer includes one or more dies, each of which has a boundary surrounding an integrated circuitry for separating one from another. One or more pattern units are disposed adjacent to the die for monitoring a fabrication process thereof. A protection structure is disposed between the die and the pattern units for preventing the die from damage during a separation of the die from the semiconductor wafer. Thus, the semiconductor wafer is adapted to prevent damage during a die separation process.

### BACKGROUND

The present invention relates generally to semiconductor designs, and more particularly to a semiconductor wafer with a protection structure against damage during a die separation process.

Integrated circuits (ICs) are produced on round semiconductor wafers. After production and electrical testing, the wafer is divided into rectangular IC chips, a.k.a. dies, by a rotary sawing operation. Provision for this operation is made with narrow scribe channels. These channels are also called scribe bands because of the history of diamond scribing. The scribe bands are sacrificial and are consumed as a “kerf loss” in the sawing operation. Dies successfully separated by the sawing operation are cleaned and delivered for bonding into a market-recognizable packaging.

During the IC design stage, the scribe bands appear as wasted space. However, that space on a semiconductor wafer has other production values. For example, that space is utilized for the construction of process control monitors (PCMs) that allow the monitoring of the many complex processes in semiconductor fabrication. Any one of these PCMs, along with any connected electric probe pads, appears, as a PCM pattern, in pattern groups. Typically, they are tested before the wafer is sawed into individual dies and the data made available by the testing are fed back to the production system to keep one or more production processes operating within specifications. These data also qualify or disqualify the wafer as having a reasonable yield of good dies. The bad dies on the wafer are marked or mapped so that only good dies move into the packaging stage.

However, the sawing operation is a relatively coarse process and damage to dies can occur since they are adjacent to the scribe bands. Damage can include, for example, flaking or chipping at the edge of a die. Damage can also include cracks that propagate into the edges and beyond, and delamination of layers of film structures.

To counter these difficulties, seal ring structures are constructed to limit or stop the progress of the damage into the critical core areas of the die. Seal rings are typically constructed within all the edges of each die, and are able to protect sensitive chip areas from one or more of the above-mentioned damages. However, with the rise of the use of new materials, additional difficulties emerge. For example, in order to reduce the speed-limiting capacitance between metal interconnection lines on the face of ICs, low-K (low dielectric constant) dielectric materials are now commonly used. Low-K dielectrics, however, have different mechanical properties than do the traditional oxide dielectrics. Because they have different stiffness properties, and weaker bonding abilities to other layers, low-K materials are more prone to delamination under the kind of stress that can be produced by sawing. This means that the PCMs, which includes low-K materials in their construction, are more likely to cause damage that progresses into dies neighboring the scribe band.

Therefore, desirable in the art of semiconductor designs are additional structures to prevent damage occurred to a die, during a die separation process.

### SUMMARY

In view of the foregoing, the following provides a semiconductor wafer adapted to prevent damage during a die separation process. In one embodiment, the semiconductor wafer includes one or more dies, each of which has a boundary surrounding an integrated circuitry for separating one from another. One or more pattern units are disposed adjacent to the die for monitoring a fabrication process thereof. A protection structure is disposed between the die and the pattern units for preventing the die from damage during a separation of the die from the semiconductor wafer.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 illustrates a typical placement of PCM patterns in scribe bands of a semiconductor wafer.

FIG. 2 illustrates a placement of protection structures in scribe bands of a semiconductor wafer, in accordance with one embodiment of the present invention.

FIGS. 3A and 3B illustrate a partial view of a semiconductor wafer having alternative protection structures, in accordance with another embodiment of the present invention.

FIG. 4 illustrates a partial view of a semiconductor wafer having a protection structure, in accordance with yet another embodiment of the present invention.

### DESCRIPTION

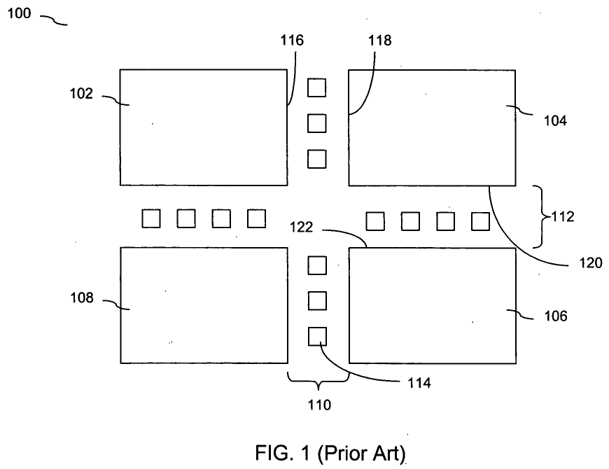

FIG. 1 illustrates a partial view of a conventional semiconductor wafer 100 with a typical placement of pattern units 114. The pattern units 114 may be PCM patterns that are used for monitoring a fabrication process of integrated circuitries in dies 102, 104, 106 and 108. Scribe bands 110 and 112 are defined vertically and horizontally among the dies 102, 104, 106 and 108, with an intersection formed thereof. A scribe band is an area, through which a rotary saw may move to separate one die from another. During a die separation process, various types of damage may occur to the die, due to the stress applied to the semiconductor wafer from the saw blade. Damage can include, for example, flaking or chipping at an edge 116 of the die 102, edges 118 and 120 of the die 104, and an edge 122 of the die 106. Damage to the aforementioned edges can also include cracks that propagate into the edges and beyond, and delamination of layers of film structures. The damage occurs particularly often, when the saw blade moves through the pattern units 114.

Because some of the pattern units 114, such as PCM patterns, are necessary during the fabrication process of the dies, some methodologies have been developed for preventing damage caused by those pattern units during a die separation process. For example, one conventional methodology is to make the pattern units 113 as slotted structures for reducing the metal density alone the scribe band. Another conventional methodology is to designate the corners of a die as exclusion zones, in which no part of an integrated circuitry shall be constructed. Thus, although chipping or cracking may occur at the corners of a die, the integrated circuitry constructed thereon remains unaffected.

Having recognized the necessity of deploying pattern units in the scribe bands of a semiconductor wafer, the present invention discloses a semiconductor wafer with a protection structure that prevents a damage from occurring during a die separation process. The protection structure is disposed between a die and its adjacent pattern units in a scribe band. When a saw blade moves through the scribe band, the protection structure helps to distribute the stress away from the die, thereby preventing an advance of damage into the die.

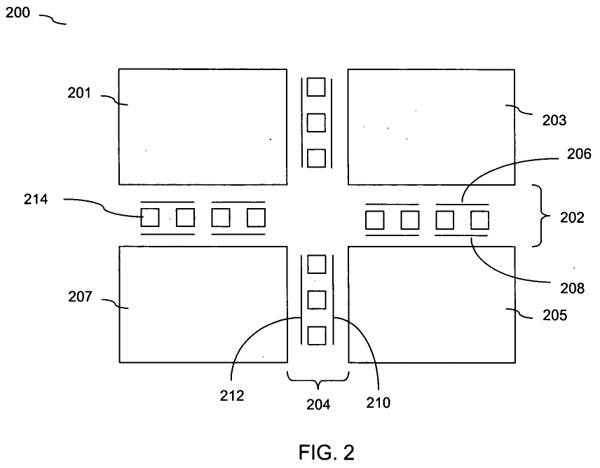

FIG. 2 illustrates a partial view of a semiconductor wafer 200, in accordance with one embodiment of the present invention. The semiconductor wafer 200 includes dies 201, 203, 205 and 207, each of which has a boundary surrounding an integrated circuitry for separating one from another. For example, the boundary may be a seal ring that extends along the four edges of a die and encloses the electrical devices and conductive lines therein. A first scribe band 202 horizontally separates the dies 201 and 203 from the dies 205 and 207, and a second scribe band 204 vertically separates the dies 201 and 207 from the dies 203 and 205. During a die separation process, a saw blade moves through the first and second scribe bands 202 and 204 to separate the dies 201, 203, 205 and 207 from each other.

One or more pattern units 214 are disposed between two neighboring dies in the scribe band 202 or 204. The pattern units may be PCM patterns that are used for monitoring the fabrication process of the integrated circuitry in the dies 201, 203, 205 and 207. In this embodiment, the pattern units are no more than about 50×70 um in size. A protection structure 206, 208, 210 or 212 is disposed between the boundary line of the die 201, 203, 205 or 207 and the pattern units 214. The protection structures 206, 208, 210 and 212 are of a linear shape, such as a continuous or discrete line. The protection structure 206 or 210 is disposed adjacent to the pattern units 214 on an opposite side with respect to the protection structure 208 or 212, respectively. During a die separation process, the pairs of protection structures 206/208 or 210/212 help to confine stress applied from a saw blade to scribe band 202 or 204 therebetween. This prevents an advance of crack, caused by the die separation process, into the die.

For each row or column of pattern units 214, the protection structures at the opposite sides are placed evenly apart from a center line of the scribe band 202 or 204 with a minimum distance allowed by a predetermined design rule. The opposite protection structures are arranged in substantially parallel. These protection structures 206, 208 201 and 212 may be made of metal or metal alloys in one or more layers. The possible candidates for the metal or metal alloys include, but not limited to, W, Al, AlCu, Cu, Ti, TiSi₂, Co, CoSi₂, Ni, NiSi, TiN, TiW, or TaN.

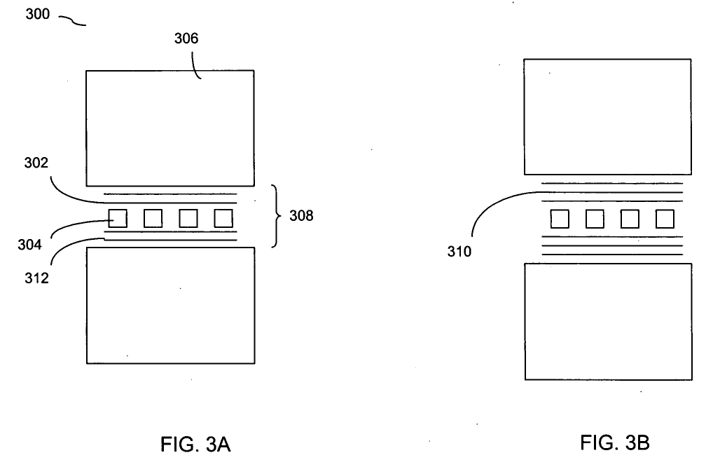

FIG. 3A illustrates a partial view of a semiconductor wafer 300 having an alternative protection structure 302 placed in a scribe band 308 between one or more pattern units 304 and a die 306. The protection structure 302 is similar to protection structures 206 or 210 shown in FIG. 2 in the above embodiment. In order to avoid repetitive description, only the key features of the protection structure 302 are stressed in the following paragraph.

The protection structure 302 includes more than one metal line for preventing an advance of crack into the die 306 during a process of separating the die 306 from a semiconductor wafer. The metal lines may be continuous or discrete. The number of the metal lines may vary. For example, while the protection structure 302 in FIG. 3A includes two metal lines, the protection structure 310 in FIG. 3B can include three metal lines. An additional protection structure 312 is placed adjacent to the pattern units 304 on an opposite side with respect to the protection structure 302. The additional protection structure 312 may or may not have the same number of metal lines as that of the protection structure 302, depending on a choice of design.

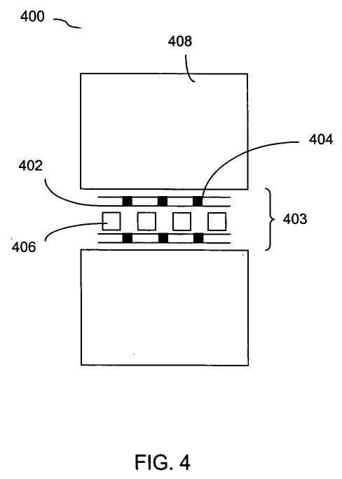

FIG. 4 illustrates a partial view of a semiconductor wafer 400 having a protection structure 402 within a scribe band 403, in accordance with another embodiment of the present invention. The protection structure 402 is similar to protection structures 206 or 210 shown in FIG. 2 in the above embodiment. In order to avoid repetition, only the key features of the protection structure 402 are stressed in the following paragraph.

The protection structure 402 includes at least two metal lines connected with one another by at least one bridge unit 404. The protection structure 402 may be placed at both sides of the pattern units 406. The protection structure 402 helps to prevent an advance of crack into a die 408 during a process of separating the die 408 from the semiconductor wafer.

As such, the present invention provides the advantages of easy construction, and low fabrication costs. The protection structures can be selectively constructed as discrete lines, continuous lines and, thereby providing various effects of stress distribution during a die separation process. Thus, the proposed semiconductor wafer with the protection structure can effectively prevent damage to the dies, during a die separation process.

The above illustration provides many different embodiments or embodiments for implementing different features of the invention. Specific embodiments of components and processes are described to help clarify the invention. These are, of course, merely embodiments and are not intended to limit the invention from that described in the claims.

Although the invention is illustrated and described herein as embodied in one or more specific examples, it is nevertheless not intended to be limited to the details shown, since various modifications and structural changes may be made therein without departing from the spirit of the invention and within the scope and range of equivalents of the claims. Accordingly, it is appropriate that the appended claims be construed broadly and in a manner consistent with the scope of the invention, as set forth in the following claims.

What is claimed is:

1. A semiconductor wafer comprising:
one or more dies, each of which has a boundary surrounding an integrated circuitry for separating one from another;
one or more pattern units disposed adjacent to the boundary of the die for monitoring a fabrication process thereof; and
a protection structure disposed between the die and the pattern units for preventing the die from damage during a separation of the die from the semiconductor wafer.

2. The semiconductor wafer of claim 1 wherein the protection structure is disposed in a scribe band, which is a saw path for separating the die from the semiconductor wafer.

3. The semiconductor wafer of claim 2 further comprising an additional protection structure disposed adjacent to the pattern units on an opposite side with respect to the protection structure in the scribe band.

4. The semiconductor wafer of claim 3 wherein the protection structure and the additional protection structure are made of metal or metal alloys.

5. The semiconductor wafer of claim 3 wherein the additional protection structure is substantially parallel to the protection structure.

6. The semiconductor wafer of claim 3 wherein the protection structure or the additional protection structure is of a linear shape in substantially parallel with the boundary of the die.

7. The semiconductor wafer of claim 6 wherein the protection structure or the additional protection structure includes at least one continuous line.

8. The semiconductor wafer of claim 6 wherein the protection structure or the additional protection structure includes at least one discrete line.

9. The semiconductor wafer of claim 8 wherein the protection structure and the additional protection structure are placed evenly apart from a center line of the scribe band.

10. The semiconductor wafer of claim 3 wherein the protection structure or the additional protection structure includes at least one set of two parallel lines connected with one anther by at least one bridge unit disposed therebetween.

11. The semiconductor wafer of claim 1 wherein the protection structure is made of metal or metal alloys.

12. The semiconductor wafer of claim 1 wherein the pattern unit is a process control monitor pattern of no more than about 50×70 um in size.

13. A protection structure for preventing damage occurred to a die during a separation of the die from a semiconductor wafer, the protection structure comprising:
one or more pattern units disposed in a scribe band which is a saw path for separating the die from the semiconductor wafer; and
one or more protection lines of a first group disposed between the die and the pattern units in the scribe band.

14. The protection structure of claim 13 further comprising one or more protection lines of a second group disposed adjacent to the pattern units on an opposite side with respect to the protection lines of the first group.

15. The protection structure of claim 14 wherein the protection lines of the first or second group are continuous lines.

16. The protection structure of claim 14 wherein the protection lines of the first or second group are discrete lines.

17. The protection structure of claim 14 wherein the protection lines of the first group and the protection lines of the second group are substantially in parallel.

18. The protection structure of claim 14 wherein the protection lines of the first group and the protection lines of the second group are placed evenly apart from a center line of the scribe band.

19. The protection structure of claim 14 wherein two adjacent protection lines of the first or second group are connected with one another by at least one bridge unit disposed therebetween.

20. The protection structure of claim 13 wherein the pattern units are process control monitor patterns.

21. The protection structure of claim 20 wherein the process control monitor patterns are no more than about 50×70 um in size.
